(19) United States
(12) Patent Application Publication
(10) Pub. No.: US 2001/0022219 A1
(43) Pub. Date: Sep. 20, 2001

(54) PLATE TYPE HEAT PIPE AND ITS MOUNTING STRUCTURE

(76) Inventors: MASAMI IKEDA, TOKYO (JP); MASAAKI YAMAMOTO, TOKYO (JP); TATSUHIRO UEKI, TOKYO (JP)

Correspondence Address: CANTOR COLBURN, LLP, 55 GRIFFIN ROAD SOUTH, BLOOMFIELD, CT, 06002

(21) Appl. No.: 09/445,360

(22) PCT Filed: Apr. 6, 1999
(86) PCT No.: PCT/JP99/01808

§ 371 Date: None

(30) Foreign Application Priority Data
Apr. 13, 1998 (JP) 99781/1998

(51) Int. Cl. F28F 7/00; F28D 15/00; F28F 3/14; H05K 7/20; H01L 23/34; B23P 15/26; B21D 53/06

(52) U.S. Cl. 165/46; 165/80.3; 165/104.33; 165/170; 361/700; 29/890.046; 257/715

(57) ABSTRACT

A plate type heat pipe comprises: (1) a container including a plate member having a surface to which a heat generating part is connected, and another plate member positioned in such manner to face the plate member and to form a hollow portion therebetween, (2) a folded portion extended outward of the container, which is formed in such manner that end portions of respective plate member and another plate member are placed to form layers, and thus placed layers are folded in one side to cause the hollow portion to be hermetically sealed, and (3) a working fluid enclosed in the hollow portion.

### FIELD OF THE INVENTION

The present invention relates to a plate type heat pipe to effectively cool heat generating parts such as semiconductor chips.

### BACKGROUND OF THE INVENTION

A method of dissipating heat by means of a plate type heat pipe attached to heat generating parts of electric or electronic components which are to be cooled (hereinafter referred to as “heat generating parts”) is considered to be an effective cooling method to cool such heat generating parts as semiconductor chips mounted on various equipment such as personal computers or power equipment so as to prevent the heat generating parts from being excessively heated.

There is briefly described about the heat pipe hereunder. The heat pipe has a hermetically sealed hollow portion (i.e., cavity) inside thereof with a working fluid enclosed in the hollow portion. The air existing inside of the hollow portion is extracted under vacuum in such manner that the inside of the hollow portion becomes to be in a condition under a reduced pressure. Accordingly, the working fluid evaporates without difficulty at a relatively low temperature. Water, alcohol, a substituted Freon or the like is used as the working fluid.

An operation of the heat pipe is briefly described in case that heat generating parts are cooled using the heat pipe. More specifically, a working fluid evaporates at the heat absorbing side of the heat pipe by means of the heat generated by the heat generating part. The heat generating part is connected to the outer surface of the heat absorbing side of the heat pipe, and the heat generated by the heat generating part is transferred through the material forming the container of the heat pipe. The vapor stream of thus evaporated working fluid moves in the interior of the heat pipe to the heat dissipating side of the heat pipe. The evaporated working fluid is caused to return from vapor phase to liquid phase at the heat dissipating side of the heat pipe when the evaporated working fluid is cooled there.

The working fluid thus returned to liquid phase flows back to the heat absorbing side of the heat pipe. Thus, the heat generated by the heat generating part is transferred from the heat absorbing side to the heat dissipating side of the heat pipe by means of the above-mentioned phase transition and movement of the working fluid accommodated in the hollow portion. The flowing back of the working fluid to the heat absorbing side is implemented by gravity or capillary action. For example, in case of the gravity type heat pipe, the heat absorbing side is positioned below the heat dissipating side in such manner that the working fluid in liquid phase at the heat dissipating side is circulated to the heat absorbing side by means of the function of gravity.

FIG. 5 shows the cross sectional view of a conventional plate type heat pipe. As shown in FIG. 5, the conventional plate type heat pipe is manufactured by the following manner. More specifically, firstly there are prepared two pieces of plate materials 70, 71, in one or both of which a recessed portion shaping the hollow portion is formed. Then, the above-mentioned two pieces of plate materials are placed to fit each other, and the edge portions 73 are welded or brazed.

More specifically, in the conventional plate type heat pipe as shown in FIG. 5, the lower plate material 71 is formed in such manner that the central portion thereof is protruded outward (i.e., downward in FIG. 5). The upper flat plate material 70 is placed to fit to the lower plate material 71, and the edge portions 73 of both plate materials thus put layered are bonded to form the hollow portion 72 therebetween. Furthermore, although not shown, there has been used the plate type heat pipe formed by the use of the upper plate material with the central portion protruded outward (i.e., upward) in the same manner as the lower plate material with the central portion protruded outward (i.e., downward).

In general, welding is applied to join the edge portions 73. However, well equipped welding facilities have to be introduced in order to weld the edge portions in such a large scale as enabling mass production, leading to a higher manufacturing cost. Furthermore, in general, good thermally conductive material such as copper or aluminum is applied to the plate material 70, 71 forming the container of the plate type heat pipe. However, since copper or aluminum material has a higher thermal conductivity, it is not easy to weld the copper or aluminum material. Accordingly, it is expected that a more effective method to join the copper or aluminum material at a lower cost is proposed.

Furthermore, as another method to join the edge portions 73 of the plate materials 70, 71, there is known a soldering. However, the bonding with the use of soldering needs such a soldering material as silver solder. In addition, there is a problem in which the soldering material has to be set in a specific manner prior to soldering, thus the cost of soldering becomes expensive. Furthermore, there is another problem in which pin holes or the like are produced in the joining portion, when soldering. Leaks occurs through thus produced pin holes or the like, leading to deteriorate the hermetically sealing of the container. In addition, flux is used when soldering. There is another problem in which the flux thus used remains in the hollow portion of the manufactured plate type heat pipe, thus leading to deteriorate the function of the plate type heat pipe.

### SUMMARY OF THE INVENTION

The object of the present invention is to provide a plate type heat pipe having a highly reliable function which can be joined at a lower cost.

The inventors have intensively studied to solve the above-mentioned problems in the conventional plate type heat pipe. As a result, it was found that it is possible to obtain the plate type heat pipe which is hermetically sealed in the same level as the conventional plate type heat pipe, the end portions of which are joined by soldering or the like, in the following manner: two pieces of the plate members forming the container of the plate type heat pipe are placed together to form layers, and the edge portions thereof are folded inwardly and thus folded edge portions are further pressed mechanically from both sides. In the above manner, the edge portions are not joined by soldering or the like.

The invention was made on the basis of the above-mentioned finding.

The first embodiment of the plate type heat pipe of the present invention comprises:

(1) a container including a plate member having a surface to which a heat generating part is connected, and another plate member positioned in such manner to face said plate member and to form a hollow portion therebetween;

(2) a folded portion extended outward of said container, which is formed in such manner that end portions of respective said plate member and said another plate member are placed to form layers, and thus placed said layers are folded in one side to cause said hollow portion to be hermetically sealed; and

(3) a working fluid enclosed in said hollow portion.

The second embodiment of the plate type heat pipe of the present invention comprises the plate type heat pipe, wherein said folded portion extended outward of said container is formed by further mechanically pressed.

The third embodiment of the plate type heat pipe of the present invention comprises the plate type heat pipe, wherein at least one protruding portion extending outward is formed on said plate member having said surface to which said heat generating part is connected, said heat generating part being connected to a surface of said protruding portion.

The fourth embodiment of the plate type heat pipe of the present invention comprises the plate type heat pipe, wherein a supporting member to support said container in a prescribed position is further provided between said container forming said hollow portion and said folded portion.

The fifth embodiment of the plate type heat pipe of the present invention comprises the plate type heat pipe, wherein said supporting member comprises said plate member and said another plate member placed in layers.

The sixth embodiment of the plate type heat pipe of the present invention comprises the plate type heat pipe, wherein said supporting member has such a prescribed shape and length that said supporting member enables said heat generating part to be contacted closely with said plate member, and said container is supported so as to be positioned on said printed wiring board by said supporting member.

The seventh embodiment of the plate type heat pipe of the present invention comprises the plate type heat pipe, wherein a nozzle portion to fill said working fluid therethrough is integrally formed as a unit on said plate member having said surface to which said heat generating part is connected.

A cooling device of the present invention comprises the plate type heat pipe as described in the fifth embodiment being arranged in such manner that said container is supported by said supporting member through said folded portion on said printed wiring board on which said heat generating member is mounted, so as to cause said heat generating member to be closely contacted with said plate member.

### BRIEF DESCRIPTION OF THE DRAWINGS

FIG. 1 is a schematic sectional view to explain an example of the forming process of one embodiment of the plate type heat pipe of the invention;

FIG. 2 is a schematic view to explain a plate type heat pipe including a nozzle portion;

FIG. 3 is a schematic sectional view of one embodiment of the plate type heat pipe of the invention and a cooling device using the same;

FIG. 4 is a schematic sectional view of another embodiment of the plate type heat pipe of the invention and a cooling device using the same;

FIG. 5 is a schematic sectional view of a conventional plate type heat pipe;

FIG. 6 is a schematic perspective view of one embodiment of the plate type heat pipe of the invention in Example 1;

FIG. 7 is a schematic perspective view of one embodiment of the plate type heat pipe of the invention in Example 2; and

FIG. 8 is a schematic perspective view of one embodiment of the plate type heat pipe of the invention in Example 3.

### DETAILED DESCRIPTION OF THE PREFERRED EMBODIMENTS

The plate type heat pipe of the invention is thermally connected to heat generating parts mounted on a printed wiring board to cool the heat generating parts. The plate type heat pipe of the invention comprises a container including a plate member having a surface to which a heat generating part mounted on a printed wiring board is connected (i.e., thermally connected), and another plate member positioned in such manner to face the plate member and to form a hollow portion therebetween; a folded portion extended outward of the container, which is formed in such manner that end portions of the respective plate member and another plate member are placed to form layers, and thus placed layers are folded in one side to cause the hollow portion to be hermetically sealed; and a working fluid enclosed in the hollow portion.

More specifically, the edge portions formed by placing the plate member and the another plate member so as to form layers are not joined by soldering, but the edge portions are folded as they are in the direction toward the side to which the heat generating part is connected to hermetically seal the hollow portion of the container. In the plate type heat pipe of the invention, the folded portion thus formed may be further mechanically pressed, thus the hollow portion is hermetically sealed more securely.

In the plate type heat pipe of the invention, there may be formed at least one protruding portion extending outward on the plate member having the surface to which the heat generating part is connected. The heat generating part is connected on the surface of the protruding portion. When the protruding portion is formed and the heat generating part is connected in close contact to the outer surface of the protruding portion, the working fluid existing in the interior of the hollow portion easily flows (circulates) into the protruding portion. Thus, the phenomenon of the so-called dry out of the working fluid is prevented from occurring.

The plate type heat pipe of the present invention further includes a supporting member positioned between the container forming the hollow portion and the folded portion, which functions to support the container in a prescribed position in relation to the printed wiring board. The supporting member comprises the portions of the plate member and the another plate member which are placed in layers. Furthermore, the supporting member has such a prescribed shape and length that the supporting member enables the heat generating part to be contacted closely with the plate member and at the same time the container is supported on the printed wiring board by the supporting member. More specifically, the portions of the plate member and the another plate member placed in a manner of layers are (bent and) extended for a prescribed length in the direction toward the side of the heat generating part, and then, the container is fixed on the printed wiring board by the support member through the folded portion which is positioned at the tip portion of the supporting member, thus maintaining the close contact with the heat generating part(s). Furthermore, although the container was supported by another specific material in the conventional cooling device using the heat pipe, the portions of the plate materials forming the container per se are used as the support member as they are, according to the present invention. Therefore, it is possible to reduce the numbers of the material components for cooling devices using the plate type heat pipe.

Copper, aluminum or the like may be used as both of the material of the plate member and the another plate member. The same material may be used for the plate member and the another plate member. Different materials may also be used for the plate member and the another plate member.

In addition, in the plate type heat pipe of the invention, a nozzle portion to fill the working fluid therethrough is integrally formed as a unit on the plate member having the surface to which the heat generating part is connected. According to the above nozzle portion, such processes may be easily implemented as to evacuate the interior of the hollow portion, to fill the working fluid and to hermetically seal the hollow portion or the like.

Furthermore, in the cooling device of the plate type heat pipe of the present invention, the container is supported by the supporting member through the folded portion on the printed wiring board on which the heat generating member is mounted so as to cause the heat generating member to be closely contacted with the plate member.

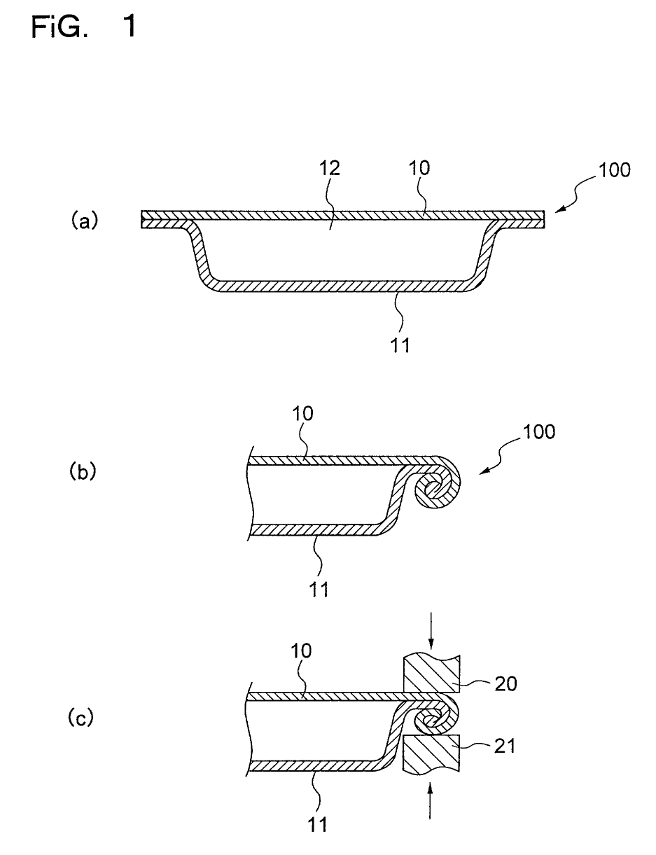

The plate type heat pipe of the invention is described with reference to drawings hereunder. FIG. 1 is a schematic sectional view to explain an example of the forming process of the plate type heat pipe of the invention.

In the plate type heat pipe of the invention, as shown in FIG. 1(a), the plate member 10 and the another plate member 11 are placed face to face (i.e., in a manner like layers), and then the edge portions 100 of thus placed plate member and another plate member are folded inwardly from the tip portions of the edge portions to form the folded portion which enable to hermetically seal the hollow portion 12. The above-mentioned edge portions of the plate member and the another plate member are as they are placed face to face and not joined by soldering.

In other words, while in the conventional plate type heat pipe, the edge portions were joined by welding or soldering so as to hermetically seal the hollow portion, in the plate type heat pipe of the invention, as described above, the edge portions which are as they are placed face to face are folded inwardly from the tip portion thereof to hold the hollow portion hermetically sealed, as shown in FIG. 1(b). In order to more securely hermetically seal the hollow portion, it is preferable that the edge portions of the layered plate member and the another plate member are folded inwardly from the tip portion as they are, and the folded portion thus formed by folding is further pressed from both sides by the molds 20, 21 as shown in FIG. 1(c).

Incidentally, in the plate type heat pipe of the present invention, the air remained in the interior of the hollow portion 12 is evacuated, and the prescribed amount of the working fluid is filled, and then the hollow portion is hermetically sealed. In order to facilitate the above working, it is general that the container is provided with the nozzle portion to fill the working fluid before sealing.

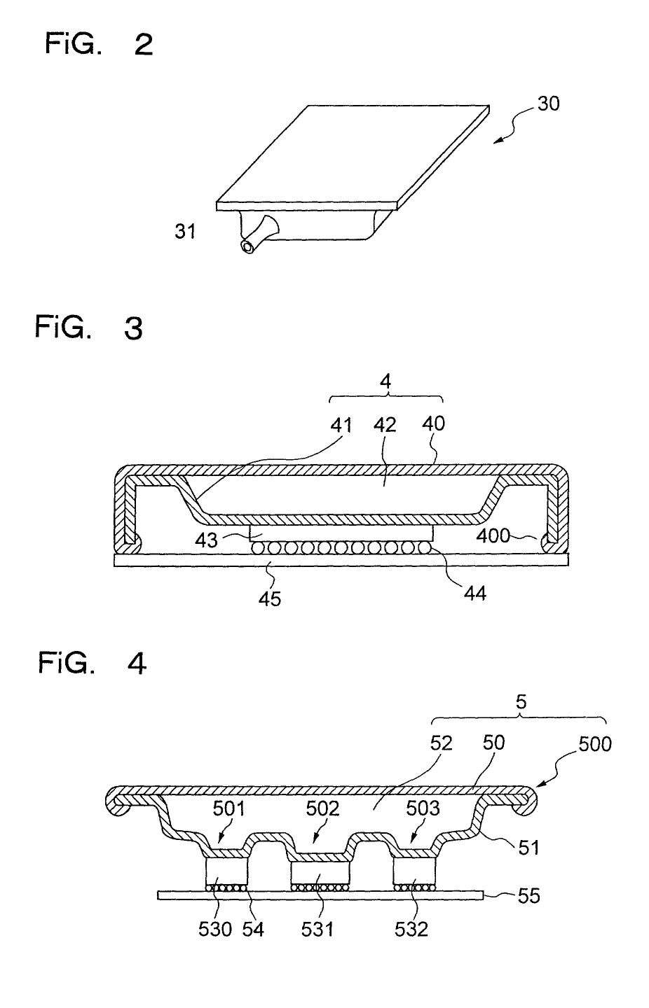

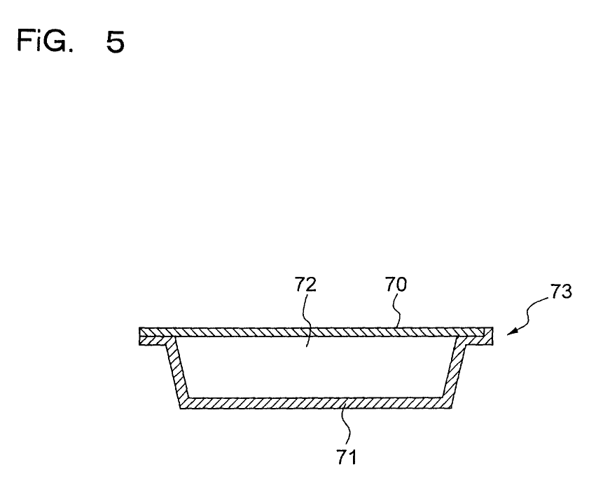

FIG. 2 is a schematic view to show an example of the container including a nozzle portion. The nozzle portion 31 shown in FIG. 2 is integrally formed with the container by burring one of the two plate members, i.e., the plate member which is bent to form the hollow portion. The plate member with the nozzle portion 31 thus formed and the another plate member are placed face to face in a manner of layers, and then the edge portions of thus placed are folded inwardly as they are, thus forming the container 30 with the hollow portion hermetically sealed. Accordingly, the plate type heat pipe can be manufactured at lower cost without implementing joining work such as soldering.

There is a cooling method to cool such heat generating parts as semiconductor chip or the like mounted on the printed wiring board with the use of the plate type heat pipe of the invention, in which the plate type heat pipe is disposed to face the printed wiring board in such manner that the semiconductor chips mounted on the printed wiring board are caused to be contacted with the plate type heat pipe, thus dissipating the heat of the semiconductor chips.

In a cooling device to cool the heat generating parts in which the plate type heat pipe is disposed to face the printed wiring board mounting the heat generating parts, it is necessary to hold the plate type heat pipe and the printed wiring board with an appropriate space therebetween and at an appropriate angle. More specifically, as shown in FIG. 3, a supporting member having a prescribed length is provided between the folded portion 400 and the container on at least two sides of the container. Each of the supporting members is extended outward and bent in the direction to the printed wiring board 45 in such manner that each of the folded portions is fixed on the printed wiring board. According to the plate type heat pipe of the invention with the supporting member provided in the above manner, numbers of the parts for forming a cooling device can be reduced, thus very effective. In FIG. 3, reference numerals 40, 41, 42, 400 respectively designate another plate member, plate member, hollow portion, and folded portion. Reference numerals 43, 44 respectively designate heat generating part and lead.

When heat generating parts mounted on the printed wiring board have different heights, it is convenient to use the plate type heat pipe 5 having the plate member having such protruding portions 501, 502 and 503 as those having corresponding heights to those of the heat generating parts, as shown in FIG. 4. Although not shown in FIG. 4, a heat sink, heat dissipating fins or the like may be attached to the upper primary surface of the another plate member of the plate type heat pipe 5. In FIG. 4, reference numerals 50, 51, 52 respectively designate another plate member, plate member, and hollow portion in this order. Reference numerals 530, 531, 532 designate heat generating parts. Reference numerals 54, 55 respectively designates lead, and printed wiring board in this order.

### EXAMPLE

The plate type heat pipe of the invention is described in detail by the examples.

### Example 1

As shown in FIG. 1(a), there are prepared a flat upper plate member 10 of copper having 130 mm in length, 75 mm in width and 1.0 mm thickness, and a lower plate member 11 of copper having 130 mm in length, 75 mm in width and 0.5 mm in width in which a rectangle convex space having 105 mm in length, 65 mm in width and 9 mm in depth is press formed at the center portion of the lower plate member to which heat generating part is connected. The above flat upper plate member 10 of copper and the lower plate member 11 of copper are placed face to face in layers to form a hollow portion 12 therebetween.

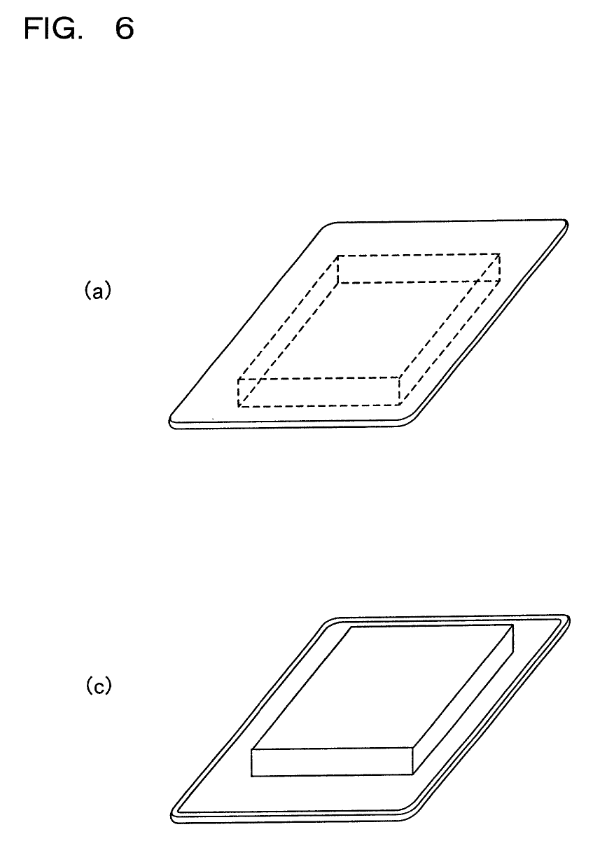

Then, the four edge portions 100 of the thus layered flat upper plate member and the lower plate member are respectively folded inwardly at a room temperature as they are without joining by soldering or the like, as shown in FIG. 1(b). Furthermore, each of the thus folded portions is pressed vertically from both sides by the power of 170 kgf/cm², as shown in FIG. 1(c) to hermetically seal the edge portions. The plate type heat pipe thus manufactured is shown in FIG. 6. FIG. 6(a) is a perspective view from the upper side of the plate type heat pipe of the invention. FIG. 6(c) is a perspective view from the back side of the plate type heat pipe of the invention.

According to the present invention, the same highly hermetically sealed plate type heat pipe as that joined by soldering can be obtained.

### Example 2

By the same manner as described in Example 1, there are prepared a flat upper plate member of copper having 130 mm in length, 105 mm in width and 1.0 mm thickness, and a lower plate member of copper having 130 mm in length, 105 mm in width and 0.5 mm in width in which a rectangle convex space having 105 mm in length, 65 mm in width and 9 mm in depth is press formed at the center portion of the lower plate member to which heat generating part is connected. The above flat upper plate member of copper and the lower plate member of copper are placed face to face in layers to form a hollow portion therebetween.

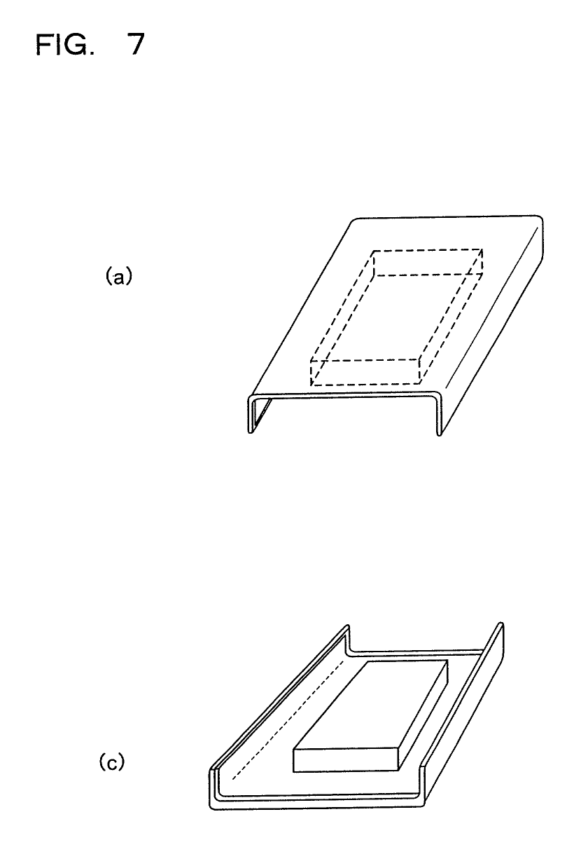

Then, as shown in FIG. 3, each of end portions is rectangularly folded downward at the portion of 15 mm from the tip of the thus layered flat upper plate member 40 and the lower plate member 41. The edge portions of thus folded end portions are further folded inwardly as shown in FIG. 3 to form the folded portions 400. The supporting members are thus formed. The supporting members thus formed support the plate type heat pipe at the height of 15 mm from the printed wiring board, while two folded portions 400 are fixed on the printed wiring board mounting heat generating parts to cause the heat generating parts to be contacted in close with the plate member, as shown in FIG. 3. The remaining edge portions of the plate type heat pipe are respectively folded inwardly at a room temperature as they are without joining by soldering or the like, as shown in FIG. 1(b) in the same manner as described in Example 1. Furthermore, each of the thus folded portions are pressed vertically from both sides by the power of 170 kgf/cm², as shown in FIG. 1(c) to hermetically seal the edge portions. The plate type heat pipe thus manufactured is shown in FIG. 7. FIG. 7(a) is a perspective view from the upper side of the plate type heat pipe of the invention. FIG. 7(c) is a perspective view from the back side of the plate type heat pipe of the invention.

According to the present invention, the same highly hermetically sealed plate type heat pipe as that joined by soldering can be obtained. Furthermore, the plate type heat pipe which enables to securely keep close contact with the heat generating parts can be obtained. Conventionally, other material member has been used as the supporting member whereas in the present invention the edge portions of the same material as the plate members can be used as the supporting member, thus enabling to reduce the numbers of the material members.

### Example 3

As shown in FIG. 4, there are prepared a flat upper plate member of copper having 130 mm in length, 75 mm in width and 1.0 mm thickness, and a lower plate member of copper having 130 mm in length, 75 mm in width and 0.5 mm in width in which a rectangle convex space having 105 mm in length, 65 mm in width and 9 mm in depth is press-formed at the center portion of the lower plate member to which heat generating part is connected. There are three outwardly protruding portions on the lower plate member with one at the center and one at each side to which the surface of the heat generating parts are respectively connected. The above upper flat plate member of copper and the lower plate member of copper are placed face to face in layers to form a hollow portion therebetween.

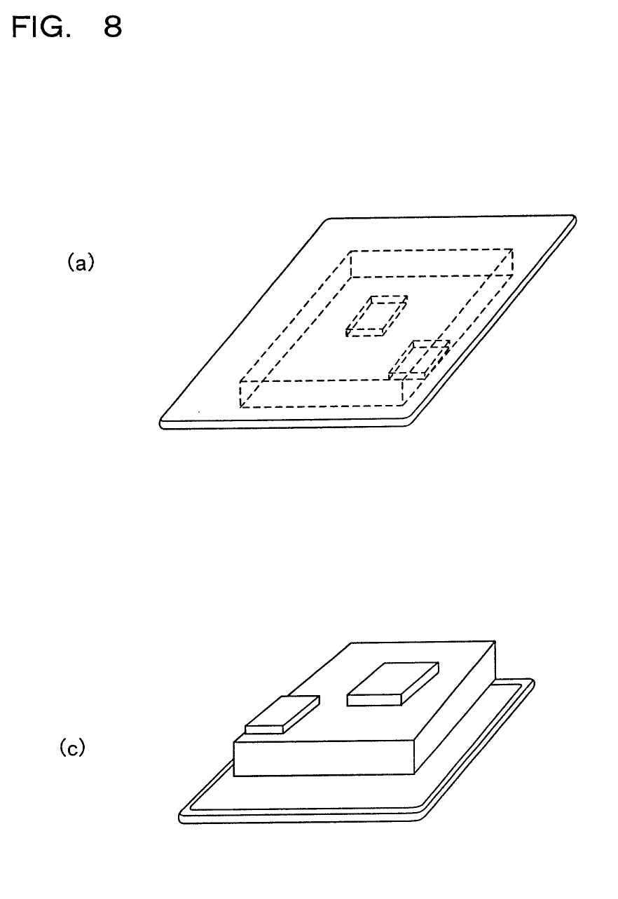

The edge portions of both longitudinal and lateral directions are respectively folded inwardly at a room temperature as they are without joining by soldering or the like, as shown in FIG. 4. Furthermore, each of the thus folded portions are pressed vertically from both sides by the power of 170 kgf/cm² to hermetically seal the edge portions. The plate type heat pipe thus manufactured is shown in FIG. 8. FIG. 8(a) is a perspective view from the upper side of the plate type heat pipe of the invention. FIG. 8(c) is a perspective view from the back side of the plate type heat pipe of the invention.

According to the present invention, the same highly hermetically sealed plate type heat pipe as that joined by soldering can be obtained. Furthermore, since heat generating parts are contacted with the outwardly protruding portions, the plate type heat pipe can be obtained in which the working fluid easily circulates (flows back) to the protruding portions, thus preventing the so-called dry out from occurring.

According to the present invention, the plate type heat pipe can be obtained at lower cost which is practical in use. Furthermore, an excellent cooling device using the plate type heat pipe can be obtained.

What is claimed is:

1. A plate type heat pipe comprises:
(1) a container including a plate member having a surface to which a heat generating part is connected, and another plate member positioned in such manner to face said plate member and to form a hollow portion therebetween;
(2) a folded portion extended outward of said container, which is formed in such manner that end portions of respective said plate member and said another plate member are placed to form layers, and thus placed said layers are folded in one side to cause said hollow portion to be hermetically sealed; and
(3) a working fluid enclosed in said hollow portion.

2. The plate type heat pipe as claimed in claim 1, wherein said folded portion extended outward of said container is formed by further mechanically pressed.

3. The plate type heat pipe as claimed in claim 1, wherein at least one protruding portion extending outward is formed on said plate member having said surface to which said heat generating part is connected, said heat generating part being connected to a surface of said protruding portion.

4. The plate type heat pipe as claimed in claim 2, wherein at least one protruding portion extending outward is formed on said plate member having said surface to which said heat generating part is connected, said heat generating part being connected to a surface of said protruding portion.

5. The plate type heat pipe as claimed in claim 3 or 4, wherein a supporting member to support said container in a prescribed position is further provided between said container forming said hollow portion and said folded portion.

6. The plate type heat pipe as claimed in claim 5, wherein said supporting member comprises said plate member and said another plate member placed in layers.

7. The plate type heat pipe as claimed in claim 6, wherein said supporting member has such a prescribed shape and length that said supporting member enables said heat generating part to be contacted closely with said plate member, and said container is supported so as to be positioned on said printed wiring board by said supporting member.

8. The plate type heat pipe as claimed in claim 1 or 2, wherein a nozzle portion to fill said working fluid therethrough is integrally formed as a unit on said plate member having said surface to which said heat generating part is connected.

9. A cooling device comprising said plate type heat pipe as claimed in claim 7 being arranged in such manner that said container is supported by said supporting member through said folded portion on said printed wiring board on which said heat generating member is mounted, so as to cause said heat generating member to be closely contacted with said plate member.
